(19) United States
(12) Patent Application Publication
(10) Pub. No.: US 2007/0096946 A1
(43) Pub. Date: May 3, 2007

(54) Information inputting system with a variable arrangement of keypad, and control method thereof

(76) Inventors: Jun-Sik Kim, Daejon-si (JP); Sang-Bin Yim, Daejon-si (KR); Byung-Sung Kim, Daejon-si (KR)

Correspondence Address: MACPHERSON KWOK CHEN & HEID LLP, 2033 GATEWAY PLACE, SUITE 400, SAN JOSE, CA, 95110, US

(21) Appl. No.: 10/552,903

(22) PCT Filed: Apr. 13, 2004
(86) PCT No.: PCT/KR04/00847

§ 371 Date: Oct. 2, 2006

(30) Foreign Application Priority Data
Apr. 14, 2003 (KR) 10-2003-0023528
Jun. 17, 2003 (KR) 10-2003-0039049
Jul. 31, 2003 (KR) 10-2003-0052939

(51) Int. Cl. H03M 11/00

(52) U.S. Cl. 341/22

(57) ABSTRACT

The present invention discloses a keypad matrix element shift arrangement method having an efficient an neighboring numeral traffic line customarily. According to the present invention, an information input apparatus whose key arrangement varies includes a key display section of a square shape for displaying a key image, and a key input section for receiving information of a corresponding key at a predetermined location of the key image displayed by the key display section. The information input apparatus further an input controller for generating an image of predetermined key arrangement selected among a plurality of key images in which numeric keys are shift-arranged so that there is no crossing in an neighboring numeral traffic line, providing the generated image to the key display section, and converting information inputted through the key input section into an actual key value according to the predetermined key arrangement.

### TECHNICAL FIELD

The present invention relates to an information input apparatus of variable key arrangement and control method thereof, and more particularly, to a secure information input apparatus and method for preventing the drain of information through peeping.

### BACKGROUND ART

In the use of various credit cards at stores, banks, etc. or financial transaction such as telebanking and Internet banking, financial accidents due to the drain of a password and personal information frequently occur. Many-sided solutions for allowing a customer to securely use his or her password and securely processing personal information and transaction information have been established. A method in which the password writing column is deleted from the paying out slip and a password input device is used when drawing the deposit or upon settlement of the credit card has been sought. Further, there has been proposed another method in which a customer's personal information and transaction information are encrypted and stored, and access thereto is controlled in order to prevent the drain of the customer information by means of bank insiders. The drain of information through network hacking has been effectively precluded with efforts of lots of security companies.

However, the customer is still in a defenseless state against physical exposure of the password and personal information in the procedure of inputting those information. When the user inputs the password and/or personal information through the keypad of the cash dispenser (CD), the automated teller machine (ATM) and the password input device (PIN pad), his or her password and/or personal information can be drained through physical methods such as peeping keys being inputted or hand movements from the surrounding, examining fingerprints left on the keys, and hearing sounds generated when the keys are depressed and so on. Moreover, peep using a hidden camera and a telescope has been spread worldwide. As such physical information drain is relatively weak, if the existing keypad is continuously used, it is expected that such peep activities will be widely made as encryption of customer information and administration for hacking prevention are stepped up.

Due to the developments of a mobile phone, a PDA and a portable computer such as a notebook computer, and widespread use of a desktop PC, CD, ATM, Kiosk, a POS (point of sale) terminal, a digital exit and entrance device such as a door lock in offices and apartments, a valuables-keeping device of a key input mode as well as financial transaction, more many information devices are being used in open place. In this case, there is a high possibility that unspecified persons within a visibility range from a user's information device may see the procedure in which the user inputs information to the information device. During the process of inputting the information, important information such as personal information, transaction information and secret information are inputted and processed. There is an urgent need for preventing the physical drain of information through peeping.

Malicious peepers such as a burglar, a spy and a privacy offender specially monitor the instant when the user inputs information. The peepers mainly spy on information through the user's monitor, keypad or hand movements. A skilled peeper can decrypt a user's input information to a considerably high degree through an instant peeping of the monitor and keypad or spy-on of hand movements. Furthermore, if the user leaves the information device after use, the peeper may decrypt the user's input information by collecting input traces such as finger traces or fingerprints, abrasion of the keypad and so on, which remain on the keypad.

### DISCLOSURE OF INVENTION

Accordingly, the present invention has been made in view of the above problems, and it is an object of the present invention to provide an information input apparatus and method in which key arrangement of a keyboard of the apparatus is variable and which can prevent a peeper from decrypting a user's input information by peeping the user's hand movements when the user inputs the information.

Another object of the present invention is to provide an information input apparatus and method in which key arrangement of a keyboard of the apparatus is variable and which can prevent a peeper from decrypting a user's input information by collecting input traces such as fingerprints or abrasion of a keypad remaining on key input means like a keypad.

Still another object of the present invention is to provide an information input apparatus and method in which key arrangement of a keyboard of the apparatus is variable and which can simultaneously satisfy convenience and security at the time of the input.

Still another object of the present invention is to provide a method and system for properly managing an information input apparatus in which key arrangement of a keyboard of the apparatus is variable.

Still another object of the present invention is to provide an information input apparatus and method, which can prevent a peeper from decrypting a user's input information by peeping a keypad from the side.

To achieve the above objects, according to the present invention, there is provided an information input apparatus whose key arrangement is variable, including: a key display section for displaying a key image of a matrix shape; a key input section for receiving information of a corresponding key at a predetermined location of the key image displayed on the key display section; and an input controller for generating an image of predetermined key arrangement selected among a plurality of key images in which numeric keys are shift-arranged so that there is no crossing in an neighboring numeral traffic line, providing the generated image to the key display section, and converting the information inputted through the key input section into an actual key value based on the predetermined key arrangement.

According to another aspect of the present invention, there is also provided a method for controlling an information input apparatus of variable key arrangement, wherein the information input apparatus includes a key display section for displaying a key image of a matrix shape and a key input section for receiving information of a corresponding key at a predetermined location of the key image displayed on the key display section, including the steps of: displaying an image of predetermined key arrangement selected among a plurality of key images in which numeric keys are shift-arranged so that there is no crossing in an neighboring numeral traffic line, and then waiting for a user's key input; and decrypting the information inputted through the key input section as an actual key value based on the predetermined key arrangement.

According to still another aspect of the present invention, there is provided a method for controlling an information input apparatus of variable key arrangement, wherein the information input apparatus includes a key display section for displaying a key image of a matrix shape and a key input section for receiving information of a corresponding key at a predetermined location of the key image displayed on the key display section, including the steps of: displaying a key image of predetermined arrangement on the key display section and then waiting for key input; if the key input is made, decrypting the information by the key input as an actual key value based on the predetermined key image arrangement; comparing the decrypted key value and legal user information to determine whether the decrypted key value is a key value of the legal user or the same hand movement key value; and if the decrypted key value is the key value of the legal user, performing a subsequent process, if the decrypted key value is the same hand movement key value, performing an illegal use process, and if the decrypted key value is neither the key value of the legal user nor the same hand movement key value, waiting for key input again.

According to still another aspect of the present invention, there is provided a private information input system for preventing the drain of information through peeping, including: means for generating a key image; means for generating a masking image that masks the key image; means for generating an image sequence for the key image and the masking image; a key display section for displaying the key image and the masking image based the image sequence; a key input section for receiving information of a corresponding key at a predetermined location of the key image displayed on the key display section; and a private input section control means for converting the information inputted through the key input section into an actual key value according to the key image.

According to the present invention, it is possible to prevent a peeper from decrypting a user's information by peeping the user's hand movements when the user inputs information. Furthermore, it is possible to prevent a peeper from decrypting a user's input information by collecting the input traces such as hand traces or fingerprints, abrasion of a keypad, etc. on a key input means. Incidentally, convenience and security in inputting keys can be improved at the same time and an illegal use attempt by a peeper can be prevented. It is also possible to prevent a peeper from decrypting information that is being inputted by a user, by peeping the information through a keyboard from the side.

### BRIEF DESCRIPTION OF DRAWINGS

Further objects and advantages of the invention can be more fully understood from the following detailed description taken in conjunction with the accompanying drawings in which:

FIG. 1a and FIG. 1b illustrate the configuration of an information input apparatus to which the present invention is applied;

FIG. 2a shows a key display, FIG. 2b shows a keypad input means, and FIG. 2c and FIG. 2d show ambient light shielding filters;

FIG. 3 is a control block diagram illustrating an example in which a dedicated display is used as a key display and a shutter is used according to the present invention;

FIG. 4 is a control block diagram illustrating an example in which a general-purpose display is used as a key display and a shutter is used according to the present invention;

FIG. 5 is a control block diagram illustrating an example in which a dedicated driver and a shutter are used according to the present invention;

FIG. 6 is a control block diagram illustrating an example in which a general-purpose monitor is used and a shutter is not used according to the present invention;

FIG. 7 is a control block diagram illustrating an example in which a dedicated display is used and a shutter is not used according to the present invention;

FIG. 8 is a flowchart illustrating a method for controlling the information input apparatus of variable key arrangement according to the present invention;

FIG. 9 is a flowchart illustrating the operation of a private information input system according to the present invention;

FIG. 10 illustrates typical keypad arrangement;

FIG. 11 illustrates random keypad arrangement;

FIG. 12 illustrates circular rotary keypad arrangement;

FIG. 13a to FIG. 13 illustrate row scroll shift keypad arrangement;

FIG. 14a to FIG. 14c illustrate row random keypad arrangement;

FIG. 15a to FIG. 15c illustrate an neighboring numeral traffic line of typical keypad arrangement;

FIG. 16a and FIG. 16b illustrate exemplary neighboring numeral traffic lines of row scroll shift keypad arrangement;

FIG. 17a to FIG. 17c illustrate exemplary neighboring numeral traffic lines of row random keypad arrangement;

FIG. 18a and FIG. 18b illustrate exemplary neighboring numeral traffic lines of row random keypad arrangement;

FIG. 19a to FIG. 19c illustrate keypad arrangement of a matrix element shift in which non-numeric keys are fixed;

FIG. 20a to FIG. 20c illustrate keypad arrangement of a matrix element shift including non-numeric keys;

FIG. 21a to FIG. 21c illustrate keypad arrangement in which a single non-numeric key is arbitrarily disposed and matrix elements are shifted;

FIG. 22a to FIG. 22c illustrate keypad arrangement in which two non-numeric keys are arbitrarily disposed and matrix elements are shifted;

FIG. 23a to FIG. 23c illustrate keypad arrangement in which non-numeric keys are fixed at the center and numeric keys are disposed so that they have a clockwise rotation traffic line;

FIG. 24a to FIG. 24c illustrate keypad arrangement in which non-numeric keys are fixed at the center and numeric keys are disposed so that they have a counter-clockwise rotation traffic line;

FIG. 25a and FIG. 25b illustrate keypad arrangement in which non-numeric keys are arbitrarily disposed and numeric keys experience a square rotary shift;

FIG. 26a and FIG. 26b illustrate keypad arrangement that is shifted in an elliptical rotary mode;

FIG. 27a and FIG. 27b show completion-type mixed images according to the present invention;

FIG. 28a to FIG. 28c show similar completion-type mixed images according to the present invention;

FIG. 29a to FIG. 29f show selection of an image composition rule, an image sequence, and a shutter opening/shutting sequence using the completion-type mixed image according to the present invention;

FIG. 30a to FIG. 30f show element image methods using the completion-type mixed image according to the present invention;

FIG. 31a to FIG. 31c are views for explaining a method for managing the same hand movement key input according to the present invention; and

FIG. 32 is a flowchart illustrating a method for managing the same hand movement key input according to the present invention.

### BEST MODE FOR CARRYING OUT THE INVENTION

The present invention will now be described in detail in connection with preferred embodiments with reference to the accompanying drawings. Like reference numerals are used to identify the same or similar parts.

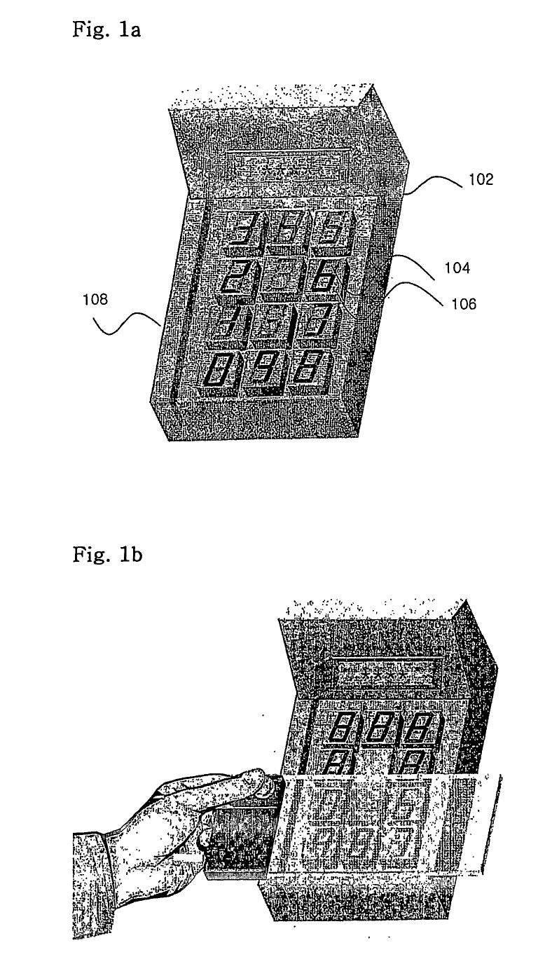

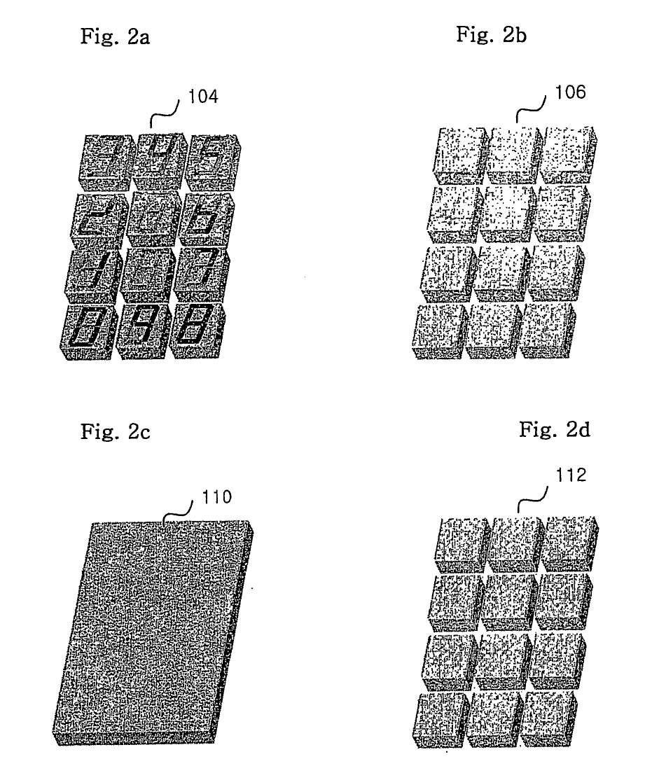

A typical system configuration of an information input apparatus of keyboard re-arrangement (variable arrangement) according to the present invention is shown in FIG. 1 and FIG. 2. FIG. 1 illustrates the configuration of the information input apparatus to which the present invention is applied, FIG. 2a shows a key display, FIG. 2b shows a keypad input means, and FIG. 2c and FIG. 2d show ambient light shielding filters.

As shown in FIG. 1, the information input apparatus of keyboard re-arrangement includes a keypad input device control system 102, a key display 104, a keypad input means 106, and a wired/wireless communication means (not shown) for connecting a host computer (not shown), if any, and the input device control system 102. The information input apparatus further includes a card reader 108 for reading a variety of information from card.

The input device control system 102 displays an image of numeric keys or character keys of predetermined arrangement corresponding to a current time point on the key display 104 according to a user's request or itself.

The key display 104 may include a general LCD, CRT or EL display monitor. For example, the key display 104 may be implemented by displaying the numeric keys or the character keys on the monitor. Also the key display 104 may be constructed with arrangement of a LED or arrangement of a simple 7-segment LED, as shown in FIG. 1a.

The keypad input means 106 may be implemented using a transparent keypad so that it covers the key display 104. Further, the keypad input means may be constructed in which each key button is located under each key of the key display 104. A variety of assembly arrangement structures of the keypad input means 106 and the key display 104 are disclosed in documents such as Korean Patent Application No. 1999-0012741. A user depresses a key located on a corresponding keypad while seeing the numeric keys or character keys of predetermined arrangement displayed on the key display 104. The keypad input means 106 sends the inputted key value to the input device control system 102.

If the information input apparatus 100 is used at the light, a problem that the contrast of an image is lowered since the ambient light reflected from the key display 104 is incident to the eyes of the eye may happen. In order to solve this problem, an ambient light shielding filter 110 or 112 such as 3M™ Privacy Computer Filters manufactured by 3M Co. Ltd. is attached to the front of the key display 104. The ambient light shielding filter is an optical filter whose optical transmittance is dependent on the incident angle and serves to shield light whose incident angle exceeds a predetermined angle. In addition, as the ambient light shielding filter shields light whose incident angle exceeds a predetermined angle, the probability that current arrangement of the keyboard is exposed to surrounding persons is reduced.

One ambient light shielding filter 110 can be attached to the entire surface of the key display 104. In this case, variety assembly methods for stacking and assembling the key display 104, the keypad input means 106 and the ambient light shielding filter 110 can be used. On the contrary, the ambient light shielding filter arrangement 112 can be attached to a corresponding key only. Even in this case, various assembly methods for stacking and assembling the key display 104, the keypad input means 106 and the ambient light shielding filter arrangement 112 can be used. Furthermore, an orthogonal two-fold ambient light shielding filter can be attached in order to shield the ambient light in all directions. The ambient light shielding filter can be attached even in a keypad input device in which a general-purpose monitor is used as the key display 104 and the keypad input means 106 such as a touch screen is used.

A keypad having a mechanical touch is usually more preferred than a touch screen keypad. In this case, it is effective to attach the ambient light shielding filter arrangement 112 to the keypad having the mechanical touch.

FIG. 1b shows the operation of a private keypad input device. In this embodiment using the 7-segment LED, a person who sees with the naked eyes will see all the keys of the keypad input device as a numeral “8”. Only an authenticated person who sees through the shutter opening/shutting means 108 can input 25 information, while seeing correct key values. By differently arranging keys of the keypad when a user inputs information, the drain of the inputted information through peeping can be fundamentally prevented.

In this embodiment, a single display screen discriminated by vertical synchronization of the monitor is referred to as a monitor frame and a piece of an image data is referred to as an image data frame. One image data frame may have the same size as one frame of the monitor or may be different from it. A private image (hereinafter, referred to as “P image”) is a private image of an authenticated user. A masking image (hereinafter, referred to as “M image”) is an image for preventing an unauthenticated person from viewing a private image of an authenticated person.

FIG. 3 is a control block diagram illustrating an example in which a dedicated display is used as the key display and a shutter is used according to the present invention. In FIG. 3, a simple dedicated display such as LED arrangement or a 7-segment LED is used as the key display and control of the private keypad input device is made by a dedicated control system.

A private input device control means 202 includes a security performance controller, an image composition rule select section, an encryption section, and an administration section. The private input device control means 202 controls an image sequence generating means 212, a shutter opening/shutting sequence and shutter opening/shutting signal generating means 214, and private and masking image generating means 216 on the basis of the display security level. In another embodiment, the private input device control means 202 further includes a user authentication section, and authenticates a user and sets/manages the display security level according to the user's authentication level. A user authentication method may be performed using a user's identification number (hereinafter, referred to as “ID”) and a password. The user authentication can be also performed by connecting an authenticated shutter opening/shutting means 108. Whether to authenticate the authenticated shutter opening/shutting means is performed through a serial number of a product built in the read only memory (ROM) (not shown) of the shutter opening/shutting means 108.

The display security level can be set by default. An operator can set the display security level at an operator interface 246 of a host computer 240, or directly set at the keypad input device. The display security level is determined according to the level of performance required in three regions: “user visual perception performance”, “naked eyes security performance” and “anti-peeper security performance”. The user visual perception performance relates to that an authenticated user is allowed to see an image clearly without visual difficulties or fatigue. The naked eyes security performance concerns that an unauthenticated person not having a shutter is not allowed to see an image clearly. The anti-peeper security performance relates to that an unauthenticated person or peeper having the shutter is not allowed to see an image clearly.

The security performance controller receives information on the display security level and then transmits proper information to the image composition rule select section, the image sequence generating means 212, the shutter opening/shutting sequence and shutter opening/shutting signal generating means 214, and the private and masking image generating means 216. The image composition rule select section selects the type of the private (P) image and masking (M) image to be composed, an average composition ratio of the P/M image, and a P/M image sequence generating methodology for generating an image sequence while maintaining the average composition ratio, according to display security level information. The image composition rule select section also selects a shutter opening/shutting sequence generating methodology. If intermediate state shutter opening/shutting is used, it is possible to select more various image composition rules. Some of the functions of selecting and managing the image composition rule of the private input device control means 202 can be performed in the host computer.

The image sequence generating means 212, the shutter opening/shutting sequence and shutter opening/shutting signal generating means 214, and the private and masking image generating means 216 generate an image sequence, shutter opening/shutting sequence and shutter opening/shutting signal, and private and masking images, respectively, according to the user's authentication level and display security level. The shutter opening/shutting sequence and shutter opening/shutting signal generating means 214 generates the shutter opening/shutting sequence corresponding to the image sequence and generates the shutter opening/shutting signal of a current time point according to the shutter opening/shutting sequence. In an embodiment, the shutter opening/shutting signal is generated with it encrypted.

The sequence controller 210 provides the key image being the private image and the masking image being the key image, which are generated in the private and masking image generating means 216, to the key display controller 204, according to the generated image sequence, while exchanging information with the private input device control means 202. The key display controller 204 displays the key image of the private image and the masking image of the key image depending on the image sequence, on the key display 104. The sequence controller 210 properly controls the shutter opening/shutting signal generated in the shutter opening/shutting sequence and shutter opening/shutting signal generating means 214 and then provides the controlled signal to the shutter opening/shutting means 108 through the P-S transceiver 208. The wired/wireless communication means 110 for transmitting the shutter opening/shutting signal to the shutter opening/shutting means 108 can be implemented using USB, a wired link such as a serial link or a wireless link such as IR and RF (FM, AM, Bluetooth).

The shutter opening/shutting means 108 may include a S-P transceiver 230, a decoder/authentication means 232, a shutter controller 234 and a shutter section 236. The S-P transceiver 230 sends the shutter opening/shutting signal received from the P-S transceiver 208 to the decoder/authentication means 232. The decoder/authentication means 232 decrypts the shutter opening/shutting signal to obtain a shutter opening/shutting sequence state value. The shutter controller 234 fully opens or half opens the shutter section 236 according to the shutter opening/shutting sequence state value. In another embodiment, the shutter opening/shutting signal can be transmitted without being encrypted and the decoder/authentication means 232 can be omitted. In still another embodiment, the shutter controller 234 may be included in the input device control system 102, and the shutter controller 234 and the shutter section 236 of the shutter opening/shutting means 108 may be constructed using a simple serial link, etc.

A keypad keyboard arrangement means 220 determines a key arrangement type and key arrangement of a current time point among the key arrangement type. In this case, a random number generator, etc. can be used. In an embodiment, a user can select the key arrangement type. The key arrangement type includes shift arrangement, rotary arrangement and random arrangement, which will be described later. The keypad keyboard arrangement means 220 sends the determined key arrangement of a current time point to the private input device control means 202. The sequence controller 210 and the private and masking image generating means 216 display an image corresponding to the key arrangement on the key display 104 through the key display controller 204 under the control of the private input device control means 202. The user can input information at the keypad 106 while privately viewing the key arrangement displayed on the key display 104. The keys inputted at the keypad 106 are read as corresponding positional key values by means of the keypad controller 206. The read positional key values are converted into actual key values according to the key arrangement of the keypad keyboard arrangement means 220. The actual key values inputted by the user are processed in the administration section of the private input device control means 202. In an embodiment, the host computer 240 sends the inputted actual key values to the host computer 240. The administration means 244 of the host computer 240 can perform subsequent processes such as authenticating a user or relaying financial transaction based on the actual key values. For instance, the administration means 244 may transmits the actual key values with them encrypted. In case of a door lock, the administration section of the private input device control means 202 can open the door after determining whether the user is an authenticated user.

FIG. 4 is a control block diagram illustrating an example in which a general-purpose display is used as the key display and the shutter is used according to the present invention.

Referring to FIG. 4, a sequence controller and a graphic driver serve to control the image. A touch screen may be used as the keypad. The private input device control means 202 includes a security performance controller, an image composition rule select section, an encryption section and an administration section. The private input device control means 202 functions to control the image sequence generating means 212, the shutter opening/shutting sequence and shutter opening/shutting signal generating means 214, and the private and masking image generating means 216 based on the display security level.

A monitor information acquisition means 308 provides information such as resolution, a refresh cycle time, vertical synchronization and horizontal synchronization, which are read form a monitor 306, to the private input device control means 202.

The sequence controller 210 provides the private and masking images generated in the private and masking image generating means 216 to a video controller 304 through a graphic driver 302 according to the generated image sequence, while exchanging information with the private input device control means 202. The video controller 304 displays the private and masking images of the key image on the monitor 306 according to the image sequence.

Furthermore, the sequence controller 210 properly controls the shutter opening/shutting signal generated in the shutter opening/shutting sequence and shutter opening/shutting signal generating means 214 and then transmits the controlled signal to the shutter opening/shutting means 108 through the P-S transceiver 208.

The keypad keyboard arrangement means 220 transmits a determined key arrangement of a current time point to the private input device control means 202. The sequence controller 210 and the private and masking image generating means 216 display an image corresponding to the key arrangement on the monitor 306 through the video controller 304 under the control of the private input device control means 202. A user can input information at the keypad 106 such as a touch screen, while privately viewing the key arrangement displayed on the monitor 306. The keys inputted in the keypad 106 are read as corresponding positional key values by means of the keypad controller 206. The read positional key values are converted into actual key values according to the key arrangement of the keypad keyboard arrangement means 220. The actual key values inputted by the user are processed in the administration section of the private input device control means 202. The input device control means 202 can perform subsequent processes such as authenticating the user or relaying financial transaction based on the actual key values.

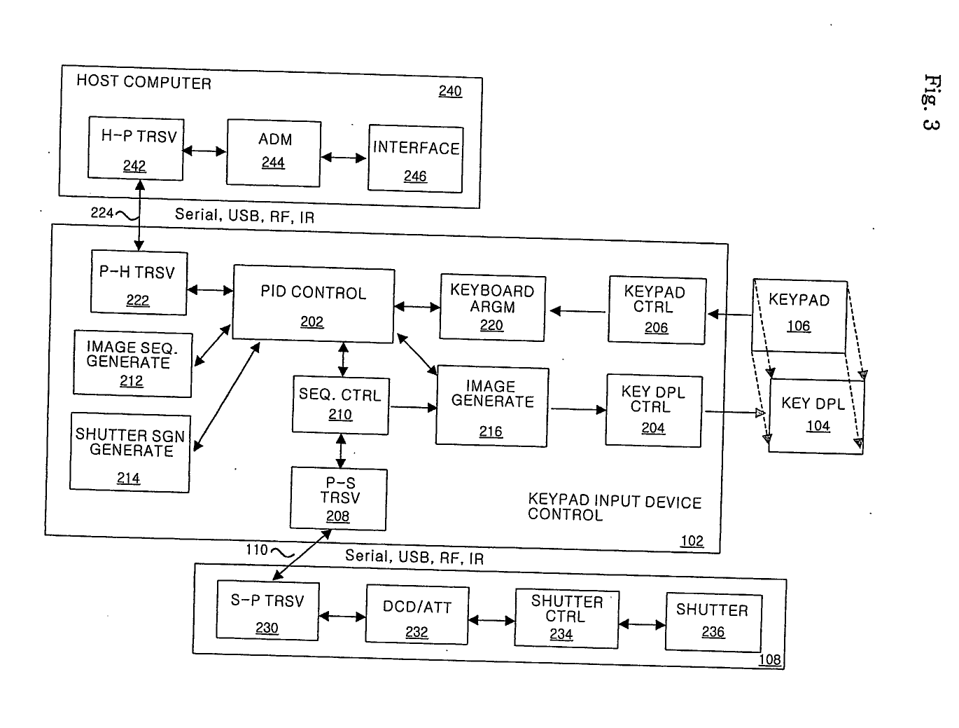

FIG. 5 is a control block diagram illustrating an example in which a dedicated driver and the shutter are used according to the present invention. The construction of FIG. 5 is the same as that of FIG. 3 except that the dedicated driver is used. In this embodiment, the dedicated driver and the graphic driver serve to control an image.

The dedicated driver 410 provides a masking image generated in a masking image generating means 418 to the video controller 304 according to the generated image sequence, or controls a color table of the video controller 304 in real time. Further, the dedicated driver 410 controls transmission of the image to the monitor 306, by allowing the video controller 304 to switch a private image memory block and a masking image memory block according to the generated image sequence.

The video controller 304 such as graphic card has a video memory, and displays the key image being the private image received from the graphic driver 302 and the masking image being the key image received from the dedicated driver 410 on the monitor 306, according to the image sequence. The image sequence is provided/controlled by the dedicated driver.

Furthermore, the dedicated driver 410 properly controls the shutter opening/shutting signal generated in the shutter opening/shutting sequence- and shutter opening/shutting signal-generating means 214 and then transmits the controlled signal to the shutter opening/shutting means 108 through the P-S transceiver 208.

FIG. 6 is a control block diagram illustrating an example in which the general-purpose monitor is used and the shutter is not used according to the present invention.

Referring to FIG. 6, a graphic driver 510 controls an image. A touch screen is used as a keypad 506. The private input device control means 504 includes a security performance controller 532, an encryption section 534 and an administration section 536, and controls the key image generating means 506 and the keypad keyboard arrangement means 508. In another embodiment, the input device control means 504 further includes a user input section 538 and displays numeric key or character key image depending on a predetermined arrangement type requested by a user on a monitor 514. In another embodiment, a user may select a key arrangement type.

The security performance controller 532 generates proper key image control information according to the user's selection or itself and transmits the generated information to the key image generating means 506 and the keypad keyboard arrangement means 508. The key image control information includes information on the key arrangement type etc.

The monitor information acquisition means 520 reads information such as resolution, a refresh cycle time, vertical synchronization and horizontal synchronization of the monitor 514 and provides those information to the input device control means 504.

The key image generating means 506 generates images of numeric keys or characters key of predetermined arrangement corresponding to the key image control information received from the security performance controller 532. The graphic driver 510 provides those key images to the video controller 512. The video controller 512 displays the key images on the monitor 514.

The keypad keyboard arrangement means 508 transmits the determined key arrangement of a current time point to the private input device control means 504. The key image generating means 506 displays the image corresponding to such key arrangement on the monitor 514 through the video controller 512, under the control of the input device control means 504. A user inputs information at the keypad 516 such as a touch screen while viewing the key arrangement displayed on the monitor 514. The keys inputted at the keypad 516 are read as corresponding positional key values by means of the keypad controller 518. The read positional key values are converted to actual key values according to the key arrangement of the keypad keyboard arrangement means 518. The actual key values inputted by the user are processed in the administration section 536 of the input device control means 504. In an embodiment, the input device control means 504 performs subsequent processes such as authenticating the user or relaying financial transaction using the actual key values.

FIG. 7 is a control block diagram illustrating an example in which the dedicated display is used and the shutter is not used according to the present invention. In this embodiment, a simple dedicated display such as LED arrangement or a 7-segment LED can be used as the key display. Control of a keyboard re-arrangement information input apparatus is performed by the dedicated control system.

An input device control means 704 includes a security performance controller 732, an encryption section 734 and an administration section 736, and controls a key image generating means 706 and a keypad keyboard arrangement means 708. In an embodiment, the input device control means 704 further includes a user input section 738 and displays numeric key or character key image according to a predetermined arrangement type requested by a user on a key display 712. In an embodiment, the user may select a key arrangement type. Such a key arrangement type includes a shift arrangement type etc., which will be described later.

The security performance controller 732 generates proper key image control information according to the user's selection or itself and transmits the generated information to the key image generating means 706 and the keypad keyboard arrangement means 708. The key image control information includes information on the key arrangement type, etc.

The key image generating means 706 generates an image of numeric keys or character keys of predetermined arrangement corresponding to the key image control information received from the security performance controller 732 and transmits the generated image to the key display controller 710. The key display controller 710 displays the key image on the key display 712.

The keypad keyboard arrangement means 708 selects key arrangement of a current time point from key arrangement types determined in the security performance controller 732. In this case, a random number generator etc. may be used. The keypad keyboard arrangement means 708 transmits the determined key arrangement of a current time point to the input device control means 704. The key image generating means 706 displays an image corresponding to such key arrangement on the key display 712 through the key display controller 710, under the control of the input device control means 704. A user inputs information at the keypad 714 while viewing the key arrangement displayed on the key display 712. The keys inputted in the keypad 714 are read as corresponding positional key values by means of the keypad controller 716. The read positional key values are converted into actual key values according to the key arrangement of the keypad keyboard arrangement means 708. The actual key values inputted by the user are processed in the administration section 736 of the input device control means 704. In an embodiment, the inputted real key values are transmitted to a host computer 740. An administration means 722 of the host computer 740 performs subsequent processes such as authenticating the user or relaying financial transaction using the actual key values. In this case, for example, the actual key values can be transmitted with them being encrypted. In case of a door lock, the administration section of the input device control means 402 can open or shut the door after authenticating the user.

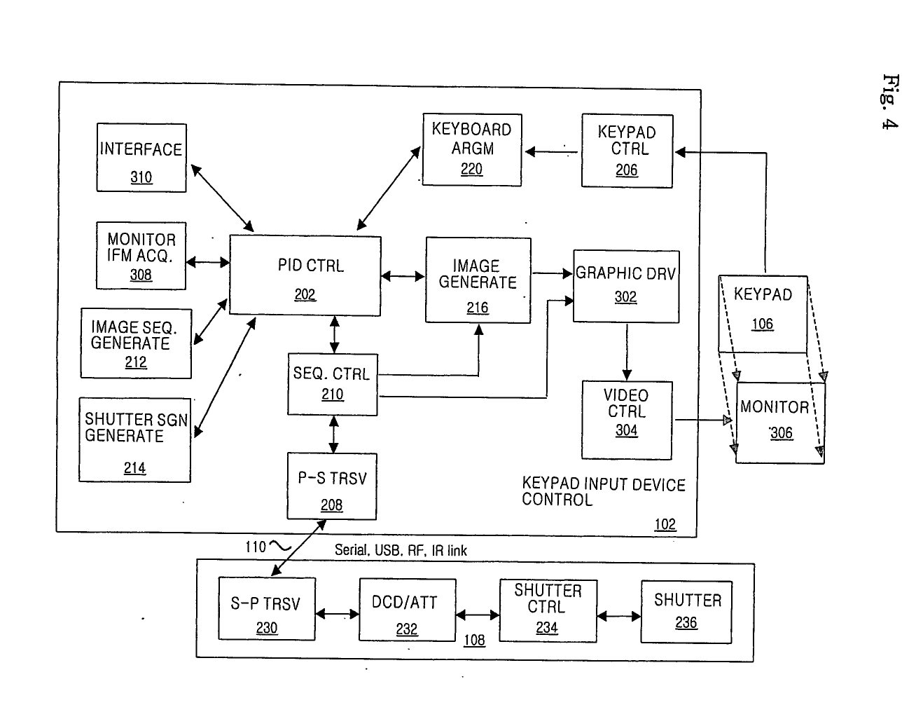

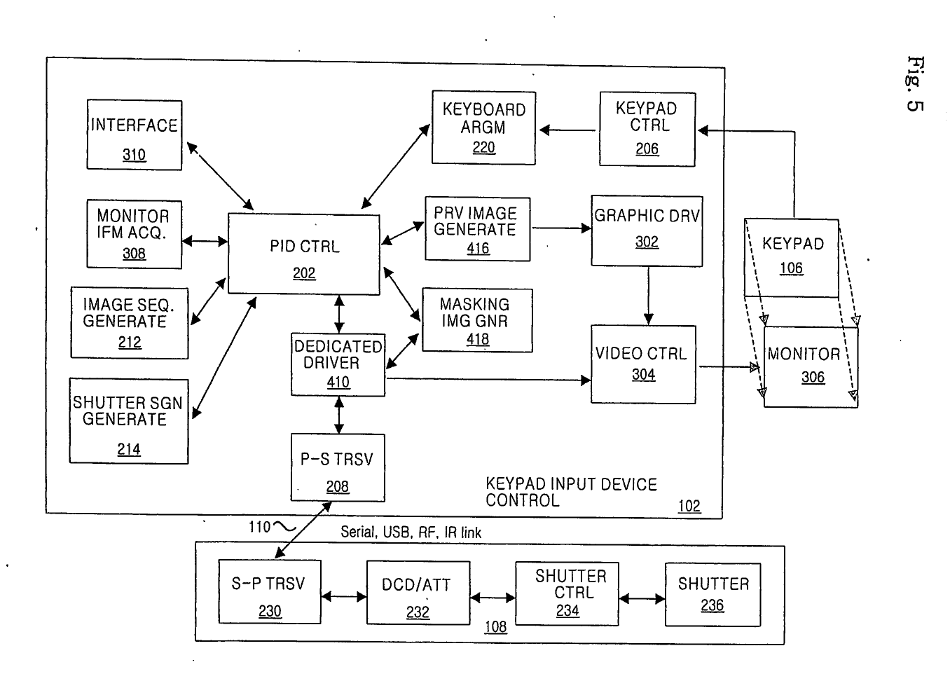

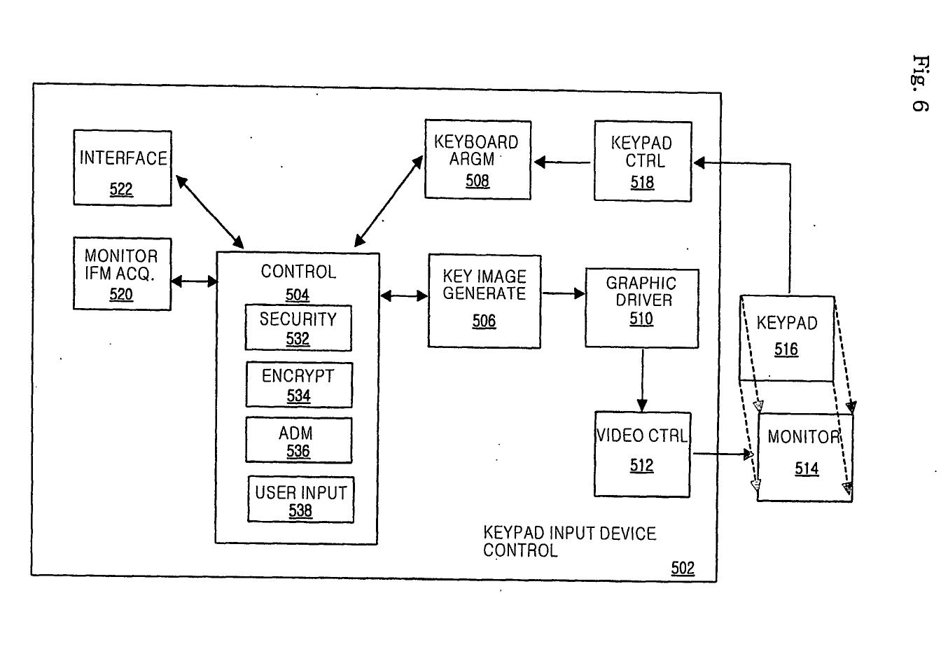

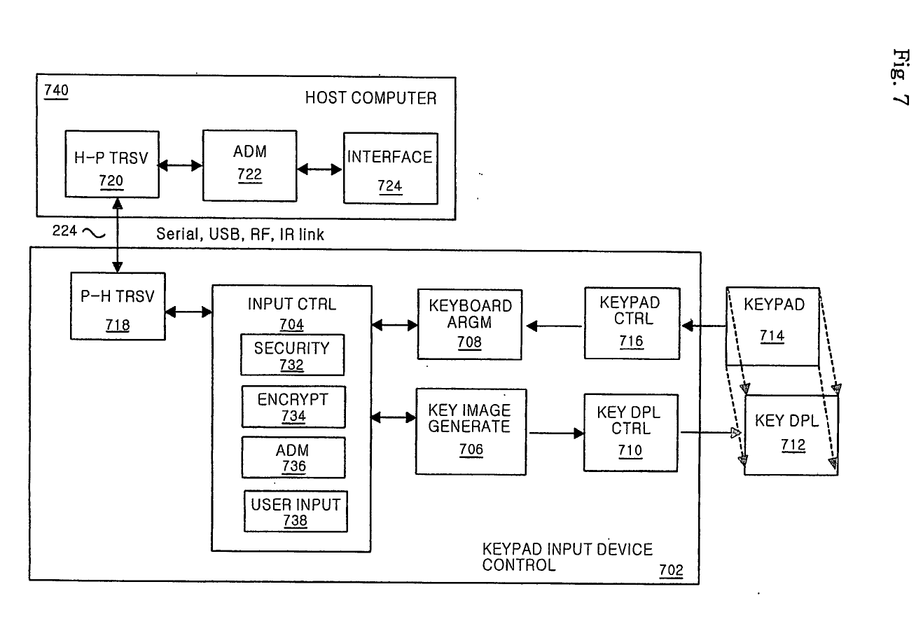

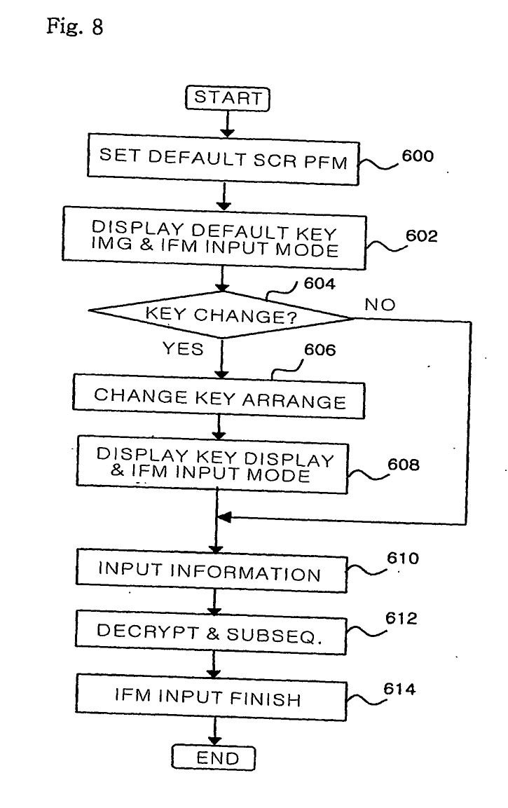

FIG. 8 is a flowchart illustrating a method for controlling the information input apparatus of variable key arrangement according to the present invention. A default display security performance level is set as a default system value by means of an operator (600). A default key image is then displayed and the process enters an information input mode where it waits for a user's use (602). The default information input mode may be a keyboard variable arrangement information input mode or a common information input mode. Thereafter, the user selects whether to change key arrangement (604). If key arrangement change is selected in step 604, a key arrangement type is changed or the key arrangement is changed (606) and the result is then displayed on the key display 104 (608). If key arrangement change is selected in step 604, the process proceeds to step 610. If the user inputs information in step 610, the inputted information is decrypted as key values and a subsequent process is then performed (612). After the user inputs the information, an input end signal is generated and the mode is switched to a default input mode (614).

In an embodiment, a key can be re-arranged every key input section and a user can input keys. In another embodiment, the keys can be re-arranged every key input unit of a predetermined number of times. For example, if two keys are inputted, they are automatically rearranged. Next two keys are inputted in a new key arrangement state.

FIG. 9 is a flowchart illustrating the operation of a private information input system according to the present invention. A private image is indicated by P, a masking image is indicated by M, and an intermediate state image is indicated by b. The intermediate state image (b) is a general term of an image not the private image (P) or the masking image (M). The intermediate state image (b) usually has an image of an intermediate shape between the private image (P) and the masking image (M) and is used to reduce a user's visual fatigue and to improve security. The intermediate state image (b) can be generated by means of the private and masking image generating means 216, 416 and 418. The image sequence composed of the private image (P), the masking image (M), the intermediate state image (b) etc, is simply referred to as a P/M image sequence regardless of whether or not the intermediate state image (b) exists in the sequence. A default display security performance level is set as a basic system value or by means of an operator (900). A default P/M image composition rule is selected according to a default display security performance level, and a default P/M image sequence and a default shutter opening/shutting sequence are generated (902). Also, a shutter opening/shutting signal of a current time point is generated based on the default shutter opening/shutting sequence. A default key image is then displayed and the process enters an information input mode where it waits for a user's use (904). The default information input mode may be a private information input mode or a common information input mode. If the user lifts the shutter opening/shutting means 108 of a panel shape from the private keypad input device in order to input private information, a signal is generated by a sensor of the shutter opening/shutting means 108 and is then sent to the input device control system 102 (906). If a use-sensed signal is received from the shutter opening/shutting means, the input device control system 102 switches to the private input mode to perform private key arrangement (908). The input device control system 102 then displays the image on the key display 104 according to the set image sequence (910). The user determines whether to change the current display security performance level (912).

If the user changes the current display security performance level in step 912, a desired display security performance level is selected (914). A P/M image composition rule is selected based on the selected display security performance level, and a P/M image sequence and a shutter opening/shutting sequence are then generated (916). Further, a shutter opening/shutting signal of a current time point is generated based on the shutter opening/shutting sequence. According to the changed image sequence, a key image is displayed and the process enters an information input mode where it waits for a user's information input (918). The user then determines whether or not to change key arrangement (920). If the user chooses to change key arrangement in step 920, a key arrangement type or key arrangement is changed (922) and the result is the displayed on the key display 104. If the uses chooses not to change key arrangement in step 920, the process proceeds to step 924. In step 924, if the user inputs information privately, the inputted information is decrypted as key values and subsequent processes are then performed (926). If the user releases the shutter opening/shutting means 108 after inputting the information, a signal is generated from the sensor of the shutter opening/shutting means 108 and is then transmitted to the input device control system 102. The input device control system 102 that received the signal switches to a default input mode to finish the user information input (928).

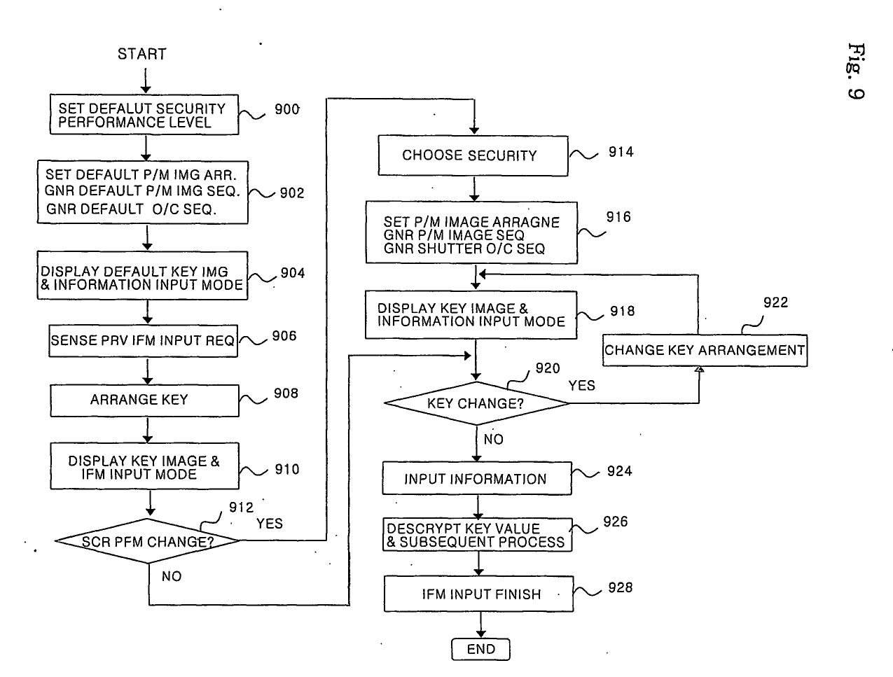

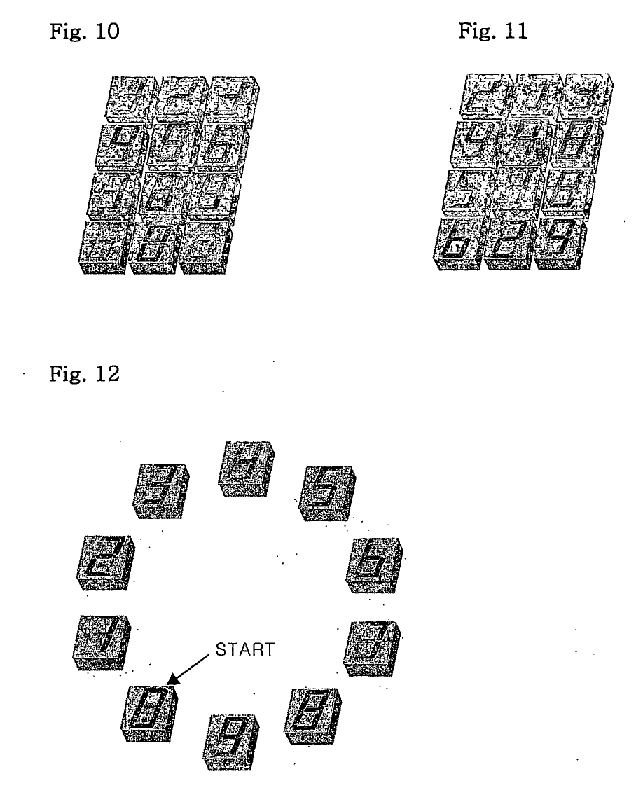

The key arrangement type will now be described. The key arrangement type includes a random arrangement type, a shift arrangement type and a rotary arrangement type. FIG. 10 illustrates a common keypad arrangement. FIG. 11 illustrates random arrangement. If the random arrangement type is used, a user may feel difficult in inputting keys. Thus, the user may use the shift arrangement type or the rotary arrangement. FIG. 12 shows an example of circular rotary arrangement using a circular keypad. In the circular rotary arrangement, the order of the keys is not changed but the starting point is arbitrarily selected.

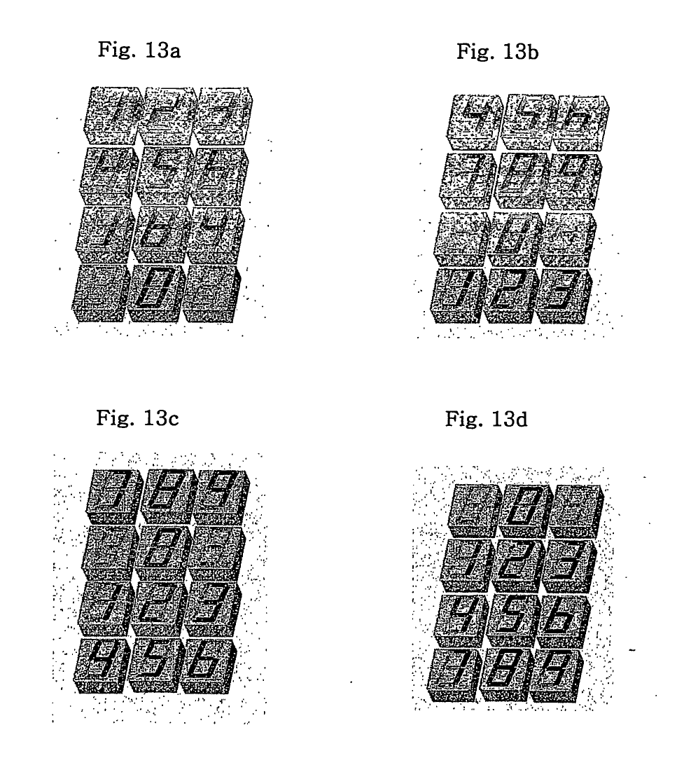

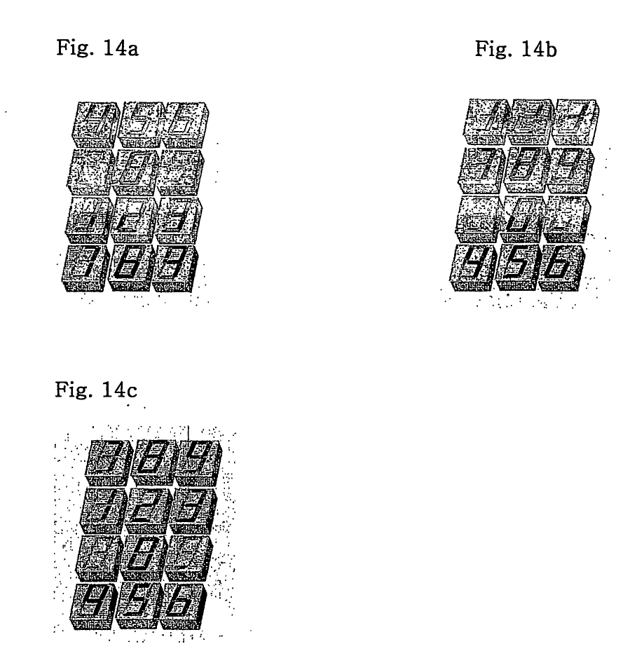

FIG. 13a to FIG. 13d are views for explaining a row scroll shift arrangement method disclosed in U.S. Pat. No. 4,857,914 (issued to Thrower). FIG. 14a to FIG. 14c are views for explaining a row random arrangement method derived from the method shown in FIG. 13a to FIG. 13d. In the row scroll shift arrangement method shown in FIG. 13a to FIG. 13d, in order to increase both convenience and security of the key input, the keyboard is variably arranged while scrolling down one row per one unit. In this case, the position of alphanumeric keys is kept intact within one row. In such a row scroll shift arrangement method, the number of all possible variable arrangement is at most four. In this case, if a peeper notices a user's information through hand movements, an exact key will be one of the four cases. Its security is thus relatively low. Furthermore, as rows having 0 have numeric keys located at the center of the numerals, if keys at the right or left column are depressed as a result of peeping the hand movement, it means that its rows do not have 0. Its security is further lowered.

The row random arrangement method shown in FIG. 14a to FIG. 14c is a method simply expanded from the row scroll shift arrangement method, wherein each row is randomly re-arranged using one row as one unit. By doing so, as the number of all possible variable arrangement is 24, security is improved. However, this method is a little better than the random arrangement method, but requires a lot of time to find an exact key and is low in convenience of the input.

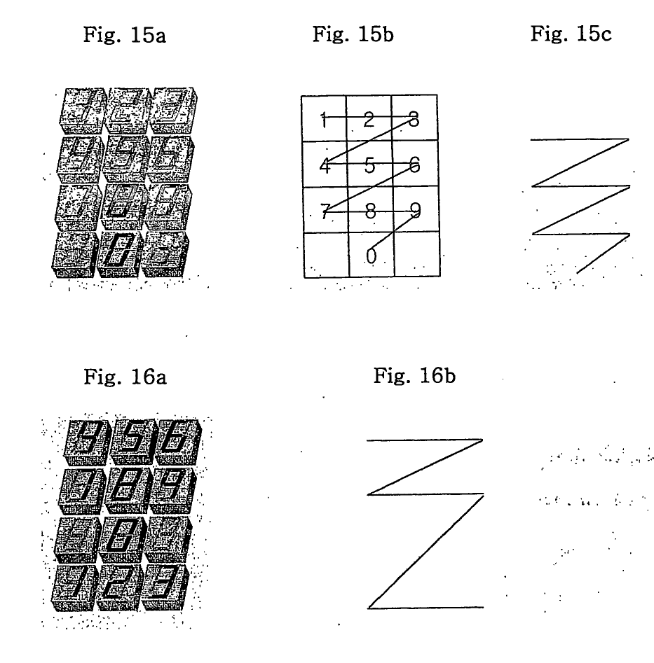

FIG. 15 to FIG. 18 are views for explaining an neighboring numeral traffic line corresponding to predetermined key arrangement according in the present invention. In the present invention, an “neighboring numeral traffic line” refers to that lines are drawn in order of their size in the keypad and neighboring numerals are arranged. In the key arrangement shown in FIG. 15a to FIG. 15c, the size of the numerals in the keypad is sequentially increasingly arranged as the neighboring numeral traffic line of typical matrix fixed arrangement. Thus, the traffic line is smooth with no crossing. The key arrangement having such a traffic line is coincident with a person's ordinary experience and custom, so that the input is convenient. Therefore, it can be said to be efficient key arrangement.

The key arrangement shown in FIG. 16a and 18b is an neighboring numeral traffic line in case of row scroll shift arrangement. In this case, the size of the numerals in the keypad is sequentially increasingly arranged. It can be thus said to be efficient key arrangement since a traffic line is smooth with no crossing.

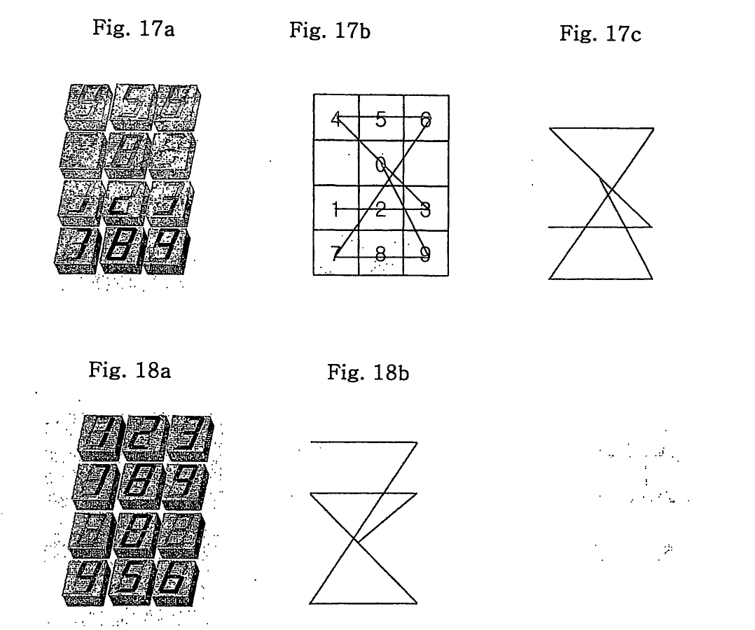

FIG. 17a to FIG. 17c and FIG. 18a and FIG. 18b show neighboring numeral traffic lines in case of row random arrangements, respectively. As the size of the numerals in the keypad is not sequentially increased, one or more crossings are generated if an neighboring numeral traffic line is drawn. This case cannot be said to be efficient key arrangement in view of custom. It results in inconvenience and an increased input time.

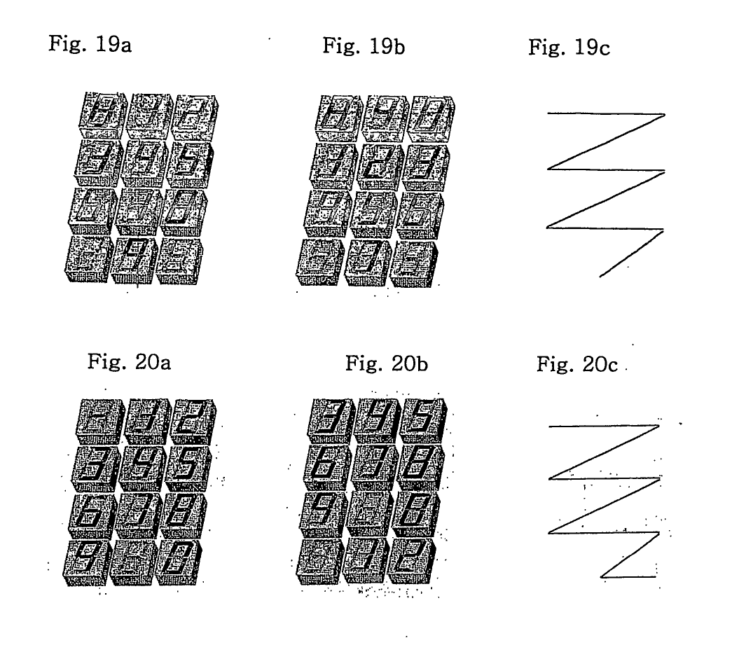

FIG. 19 to FIG. 22 show keypad matrix element shift arrangement methods according to the present invention. FIG. 19a to FIG. 19c show two cases of methods in which non-numeric keys (usually indicated by *, # etc.) are fixed and keypad matrix elements are shifted, and an neighboring numeral traffic line. In these methods, security is relatively high since there are 10 arrangement methods. It can be also said to be efficient key arrangement since the neighboring numeral traffic line is smooth with no crossings, as can be seen from the drawings. However, if the arrangement is not made beginning numerals such as 1 and 2 at the top, it may result in inconvenience and an increased time since it is inconsistent with custom.

FIG. 20a to FIG. 20c show two cases of methods for shifting keypad matrix elements including non-numeric keys, and an neighboring numeral traffic line. In these methods, security is a little high since there are all 12 arrangements. It can be said to be efficient arrangement since an neighboring numeral traffic line is smooth with no crossings, as can be seen from the drawings. However, if the arrangement is not made beginning numerals such as 1 and 2 at the top, it may result in inconvenience and an increased time since it is inconsistent with custom.

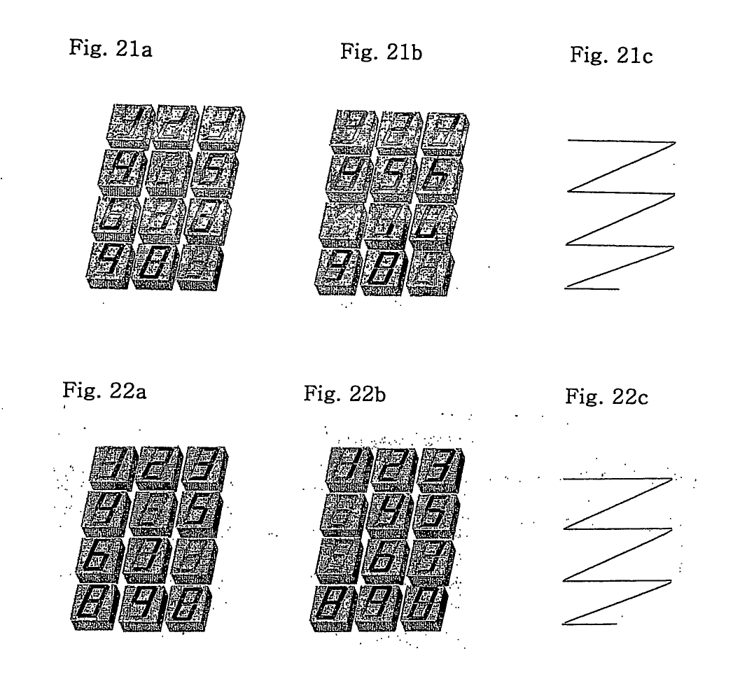

FIG. 21a to FIG. 21c show two cases of methods in which with one non-numeric key fixed, the other non-numeric key is arranged at a predetermined location in a typical matrix arrangement, and keypad matrix elements are shifted from the location of the non-numeric keys, and an neighboring numeral traffic line. In these methods, security is relatively high since there are 11-arrangement cases. It can be said to be efficient key arrangement since an neighboring numeral traffic line is smooth with no crossings, as can be seen from the drawings. Moreover, as arrangement is performed beginning numerals such as 1 and 2 at the top, it is coincident with custom. Thus, there is almost no inconvenience and an increased input time since.

FIG. 22a to FIG. 22c show two cases of methods in which two non-numeric keys are arranged at a predetermined location in typical matrix arrangement and keypad matrix elements are shifted from the position of the non-numeric keys, and an neighboring numeral traffic line. In these methods, security is high as there are all 121 arrangement. It can be thus said to be efficient key arrangement since an neighboring numeral traffic line is smooth with no crossings as can be seen from the drawings. Further, as arrangement is always made at the top beginning numerals such as 1 and 2, it is coincident with custom. Accordingly, there is almost no inconvenience and an increased input time. As another embodiment, there is a method in which with one non-numeric key fixed, the other non-numeric key is arranged at a predetermine location, and keypad matrix elements are arbitrarily shifted. In this method, arrangement needs not to be always made beginning numerals such as 1 and 2 at the top. As still another embodiment, there is a method in which two non-numeric keys are arranged at a predetermined location and keypad matrix elements are arbitrarily shifted.

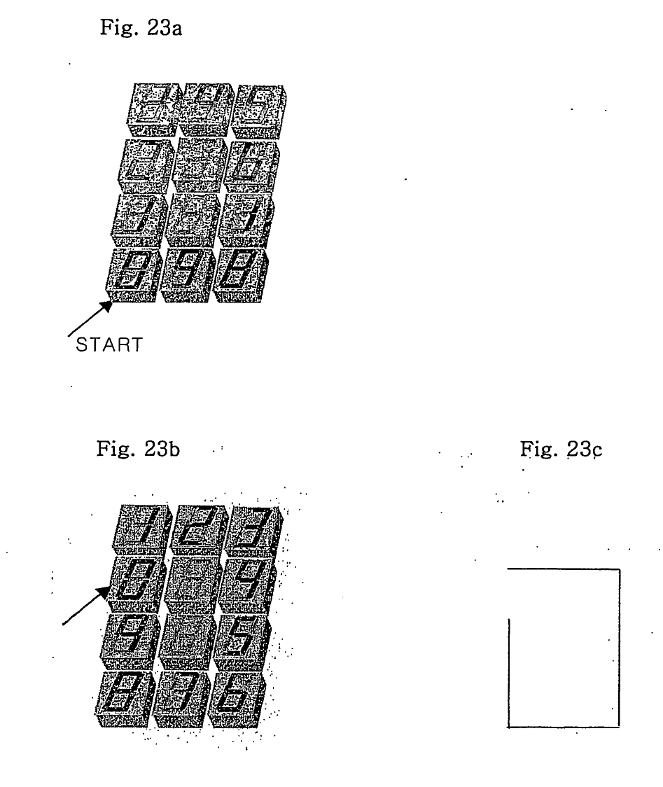

FIG. 23 to FIG. 26 show square rotary shift arrangement methods of keypad matrix elements according to the present invention. FIG. 23a to FIG. 23c show keypad matrix elements shift methods of a clockwise square rotary mode in which non-numeric keys are fixed at the center. It can be said to be efficient key arrangement since an neighboring numeral traffic line is smooth with no crossing. Although there is a case where arrangement may not be made beginning numerals such as 1 and 2 at the top, there is almost no inconvenience and time increase in input since a person used to depress a circular dial key button. In this square rotary arrangement, the order of the keys is not changed and the starting point is arbitrarily selected.

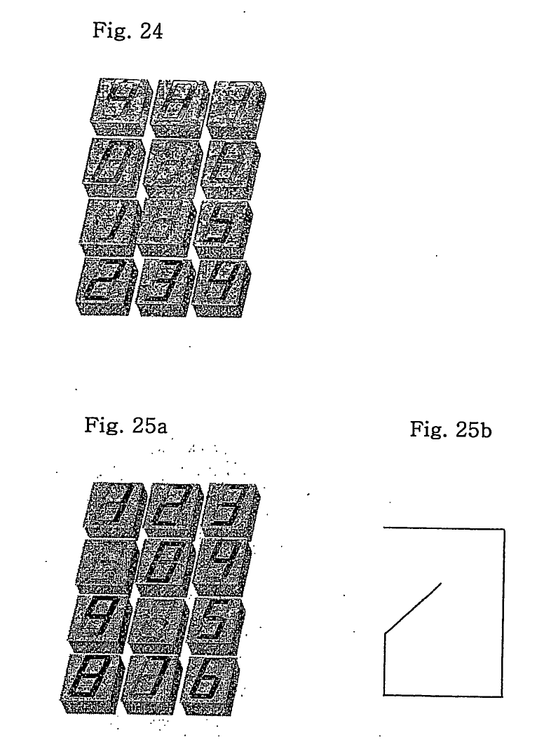

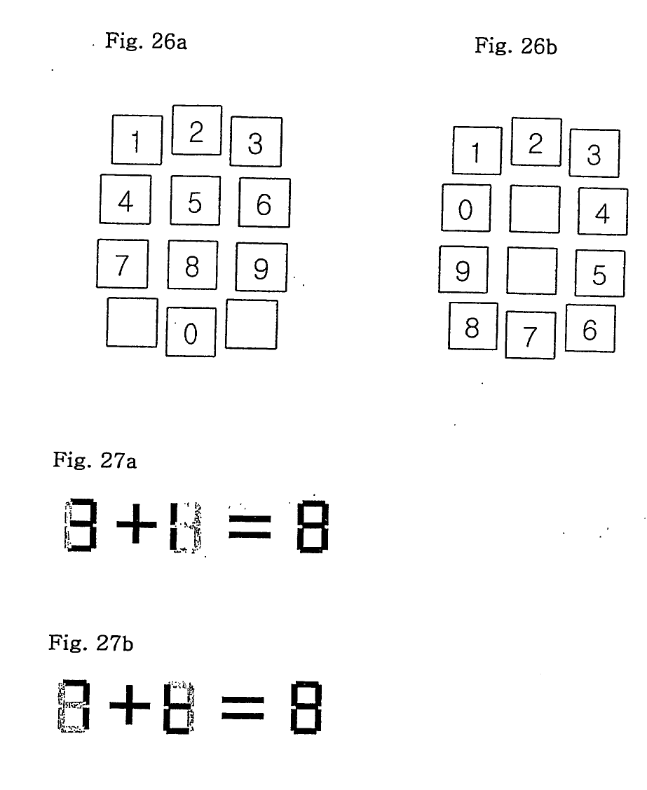

FIG. 24 shows the same method as those of FIG. 23a to FIG. 23c except that it adopts a counterclockwise rotation of square rotary mode. FIG. 25a and FIG. 25b show a key matrix element shift method of a clockwise rotation square rotary mode in which non-numeric keys are arranged at a predetermined position according to another embodiment of the present invention. FIG. 26a and FIG. 26b show elliptical rotary modes having a keypad of a square elliptical shape according to an embodiment of the present invention.

In an embodiment of the present invention, in a keypad in which multiple numeric keys and multiple character keys are allocated to a single key like a mobile phone keypad, as the keys are variably arranged, the character keys as well as the numeric keys are variably arranged at a new location and are displayed accordingly. Accordingly, characters and numerals can be inputted with some degree of security according to the method of the present invention.

FIGS. 27a and 27b show completion-type mixed images according to the present invention. Private and masking images generated by the private and masking image generating means 216, 416 and 418 are time-sequentially displayed on the display device 104 in real time according to the image sequence. In this case, if the mixed images seen with the naked eyes without using the shutter opening/shutting means are seen as a single image having a specific meaning regardless of the private image, it is defined as “a completion-type mixed image”. Further, a masking image, which is time-sequentially mixed with a predetermined private image to produce the completion-type mixed image, is defined as “a completion-type masking image”. For example, if the masking image as shown in FIG. 7a is generated as the completion-type masking image when the private image is 3 and the masking image as shown in FIG. 7b is generated when the private image is 7, the mixed image is seen as 8 as a single one. Likewise, if completion-type masking images are selected and mixed for all the numerals, completion-type mixed images that are all seem as 8 can be produced.

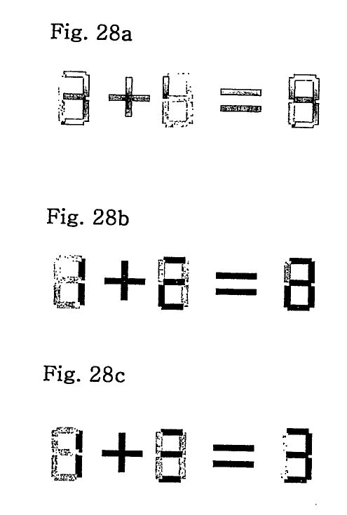

FIG. 28a to FIG. 28c show similar completion-type mixed images according to the present invention. A masking image, which produces a mixed image that looks similar a completion-type mixed image shown, is generated. A collection of such mixed images is referred to as a “similar completion-type mixed image collection”. A masking image that produces a similar completion-type mixed image is referred to as a “similar completion-type masking image”. In this case, a variety of similar completion-type masking images can be produced for a single private image. FIG. 28a to FIG. 28c show keypads having a 7-segment LED. If the completion-type mixed image is 8, the similar completion-type mixed image is an image similar to 8. At this time, an image in which some are deleted from 8 or a predetermined stroke is added to 8 is possible. For instance, the private image 3 can be made look like a mixed image 9, as shown in FIG. 28a. The private image 1 can be made look like 6 or 3 whose right and left are changed, as shown in FIG. 28b and FIG. 28c. As such, a similar completion-type masking image that can make various kinds of similar completion-type mixed images is possible depending on the type of the private image.

Although the embodiment of the keypad having the 7-segment LED has been described so far, the completion-type mixed image method and the similar completion-type mixed image method can be applied to the keypad having the common general-purpose display. As the general-purpose display device has the number of pixels greater than the 7-segment LED, the numbers can be represented with various fonts. In an embodiment, in the keypad having the general-purpose display, the numbers are displayed and inputted using the numeric representation of fonts having the same as the keypad having the 7-segment LED. In another embodiment, the numbers are displayed and inputted using the numeric representation of other fonts that cannot be implemented in the 7-segment LED. At this time, the completion-type mixed image does not have a simple shape such as 8 but has a complicated shape in which numbers that can be displayed using the fonts are all overlapped. In the completion-type masking image, the numerals other than the numerals corresponding to the private image can have a shape in which they are all overlapped. In the completion-type mixed image generated by this method, lots of numerals are seen at the same time. It is thus impossible for a peeper to exactly identify private image numerals with the naked eyes.

In order to produce the completion-type mixed image, in a preferred embodiment, images are generated so that the private images and the completion-type masking images are displayed in almost the same mixed ratio in time, thus allowing an exact completion-type mixed image to be seen. In another embodiment, images are generated by making different the time composition ratio of the private images and the completion-type masking images. If the ratio of the private images and the ratio of the completion-type masking images are differently composed, contrast of the images becomes irregular, so that the completion-type mixed image can be made look like the similar completion-type mixed image. Even in this case, if the image sequence varies in time according to the image composition rule, the display security performance of the private input device is not lowered.

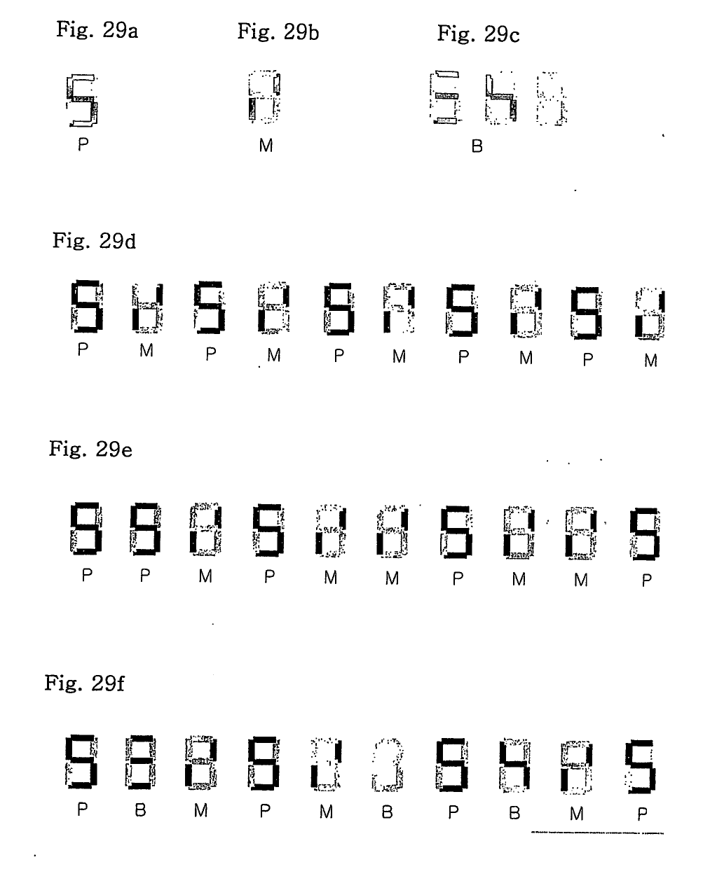

FIG. 29a to FIG. 29f illustrate selection of an image composition rule, an image sequence and a shutter opening/shutting sequence using the completion-type mixed image according to the present invention. This drawings illustrate a masking image and an intermediate state image for a private image (numeral 5). A period image sequence and a non-period image sequence can be each implemented using the private image (FIG. 29a) and the masking image (FIG. 29b,) as shown in FIG. 29d and FIG. 29e. FIG. 29f illustrates an image sequence including the intermediate state image (FIG. 29c). The intermediate state image may have some of the private image, as described above.

In order to produce the completion-type mixed image, it is preferred that the private image and the completion-type masking image are mixed in almost the same ratio in time. In another embodiment, the mixed image can be made look like the similar completion-type mixed image by differently mixing the ratios of the private image and the completion-type masking image. If the mixing rule such as the mixing ratio of the private image (FIG. 29a) and the completion-type masking image (FIG. 29b) is defined, an image sequence is generated. In an embodiment, in order to reduce a user's visual fatigue as shown in FIG. 29d, the image sequence may be set so that the private image and the completion-type masking image are periodically repeatedly seen. In another embodiment, the image sequence can be seen so that the private image and the completion-type masking image are seen as a non-periodic sequence format having a predetermined rule, as shown in FIG. 29d.

In an embodiment of the present invention, the intermediate state image (FIG. 29c) being the medium between the private image and the masking image is generated and can be displayed along with a predetermined image sequence. In this embodiment, the images are displayed as the private image (P), the masking image (M) and the intermediate state image (b), respectively. For example, the period image sequence as shown in FIG. 29d, the non-period image sequence (PBMPMBPBMP) as shown in FIG. 29e, and the sequence (PPMPMMPMMP) having the intermediate state image as shown in FIG. 29f can be generated. In the event that the image sequence having the intermediate state image is generated, it is preferred that the time average frequency of each portion of the image is uniformly set.

A shutter opening/shutting sequence can be implemented as a shutter opening/shutting state sequence having 2-state shutter opening/shutting or intermediate state shutter opening/shutting. In the 2-state shutter opening/shutting, the shutter is wide opened at the time of the private image and the shutter is shut by maximum at the time of the masking image. In the 2-state shutter opening/shutting embodiment, if the shutter opening/shutting sequence is non-periodic, the period that the shutter is opened and shut is irregular. It may result in lots of fatigue in the user's eyes. In the shutter opening/shutting having the intermediate state shutter opening/shutting, at least one intermediate state is added in addition to the opening and shutting, so that the shutter is opened and shut. In an embodiment of the present invention, if the opening/shutting state of the shutter consistently continues, it is possible to effectively reduce the fatigue of the eyes due to irregular opening/shutting of the shutter by opening and shutting the shutter in the intermediate state and manipulating the image accordingly.

If the intermediate state image is to be displayed, in an embodiment, the shutter can be opened and shut in the intermediate state. In another embodiment, the shutter can be opened and shut in a closed or opened state. In another embodiment, if the private image or the masking image is to be displayed, the shutter can be opened and shut in the intermediate state. In the case where the intermediate state image is to be displayed, if the shutter is opened and shut in the intermediate state, the private image and the masking image can be smoothly replaced. It is also possible to prevent a decrease in the recognition ratio of the private image due to the image formed in the eyes when the shutter is opened and shut in the intermediate state. In an embodiment, when the shutter is opened and shut in the intermediate state, some or all of a private image is shown as shown in FIG. 9, thus increasing the recognition ratio of the private image.

The image composition rule, image sequence and shutter opening/shutting sequence using the similar completion-type mixed image can be easily selected by referring to FIG. 9, which shows an embodiment using the completion-type mixed image.

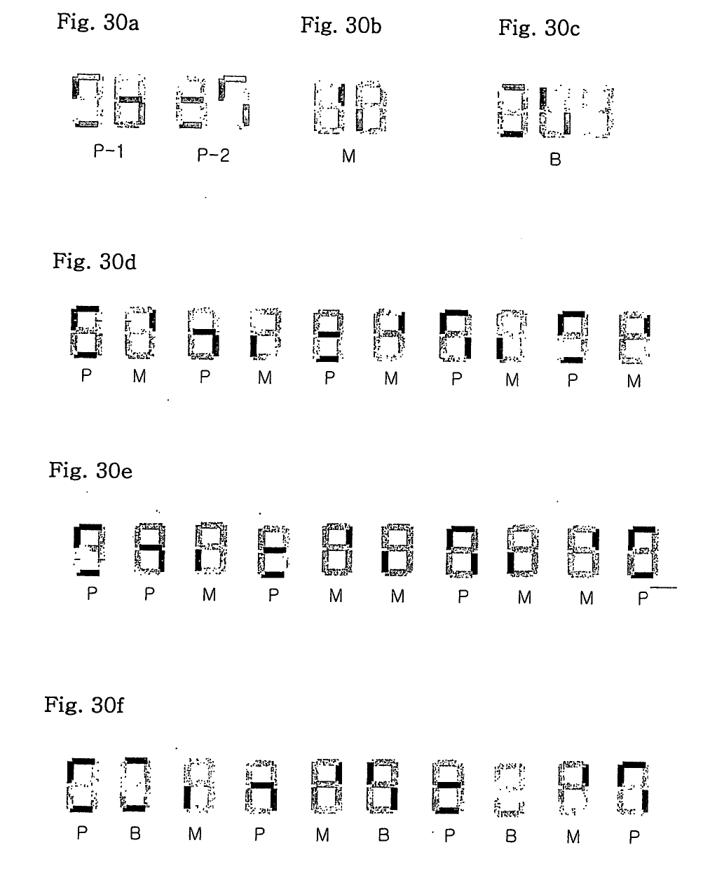

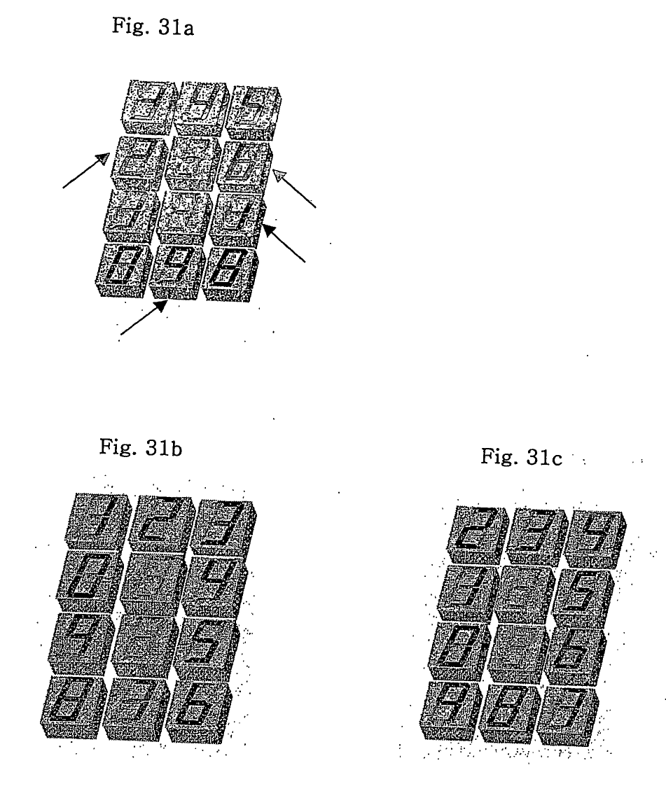

FIG. 30a to FIG. 30f show element image methods using the completion-type mixed image according to the present invention. In the event that the completion-type mixed image as shown in FIG. 27a and FIG. 27b is used, if a peeper peeps the image using a non-allowed shutter opening/shutting means or continuously takes a picture of the image using a high speed camera, numeral arrangements to be hidden can be exposed at some time. In order to prevent such a condition, in an embodiment of the present invention, the private image and the completion-type masking image for each numeral are divided into respective elements and are then time-sequentially mixed. In the same manner, the intermediate state images can be also divided into dividing element. This method is hereinafter referred to as an “element image method”. The divided elements of the private image are referred to as a “private image element”. The masking image and the intermediate state image are referred to as a “masking image element” and an “intermediate state image element”, respectively. In the element image method, a plurality of methods may exist in dividing the image element. The image sequence can be constructed by applying a plurality of the dividing methods at the same time. In the element image method, the element dividing method and the image element sequence may vary arbitrarily. Therefore, a peeper can see only private image elements or masking image elements through the unauthenticated shutter opening/shutting means or the high-speed camera. It is thus impossible to induce meaningful private images.

In order to produce the completion-type mixed image, it is preferred that the private image elements and the completion-type masking image elements are mixed in almost the same ratio in time. In another embodiment, the ratio of the private image element and the ratio of the completion-type masking image element are differently mixed so that the mixed image is made look like the similar completion-type mixed image. If the element image method is used, an exact private image can be seen only when consecutive private image elements are seen for a predetermined time through an authenticated shutter.

In the element image method, the sequence of the private image elements and the masking image elements can be periodically set as in FIG. 30d. If the sequence of the private image elements and the masking image elements is generated as a non-periodic sequence as in FIG. 30e, security against a peeper who wears an unauthenticated shutter can be significantly improved. Although fatigue of a user's eyes is increased when the sequence of the private image elements and the masking image elements is used as the non-sequence, security against the peeper can be improved while reducing fatigue if displaying it as an image sequence having the intermediate state image element and using the intermediate state shutter opening/shutting as shown in FIG. 30f.

In an embodiment, FIG. 10 shows an example of an element image method for the numeral 5. The private image element, the masking image element and the intermediate state image element can be divided as shown in FIG. 30a to FIG. 30c. If they are displayed as a periodic image element sequence or a non-periodic image element sequence, a user can comprehensively see the private image as an integral value of the private image elements. In an embodiment, the private image element for the numeral 5 in FIG. 30a to FIG. 30f can be divided in various manners like P-1 or P-2. In the same way, in dividing the masking image element and the intermediate state image element, a plurality of examples may exist. Only one example is shown in FIG. 30a to FIG. 30f. In an embodiment, as shown in FIG. 30d to FIG. 30f, two private image elements P-1 and P-2 can be displayed with them mixed. FIG. 30f shows an example of an image sequence including a divided intermediate state image element. The element image method using the similar completion-type mixed image can be easily induced from the element image method using the completion-type mixed image.

FIG. 31a to FIG. 31c are views for explaining a method for managing the same hand movement key input according to the present invention. In the present invention, the “same hand movements key” refers to a pair of keys that have to be inputted through the same hand movements every case when the keypad is variably arranged. For instance, in case of a keypad using a clockwise rotation square rotary arrangement method, a variety of arrangements are possible as shown in FIG. 31a to FIG. 31c. If four digits of a password “6927” are inputted in the arrangement state of FIG. 31a, four keys indicated by arrows are inputted, as shown in the drawing. In this case, the same hand movement key is “4750” in case of FIG. 31b, and “5816” in case of FIG. 31c. In this embodiment, in case of a clockwise rotation square rotary arrangement keypad, “6927”, “4750”, “5816”, etc. are managed as the same hand movement keys. If a peeper exactly peeped the user's hand movements, the peeper will know “6927”, “4750”, “5816”, etc. as possible password candidates. The peeper will try to know an exact password by inputting all the possible password candidates.

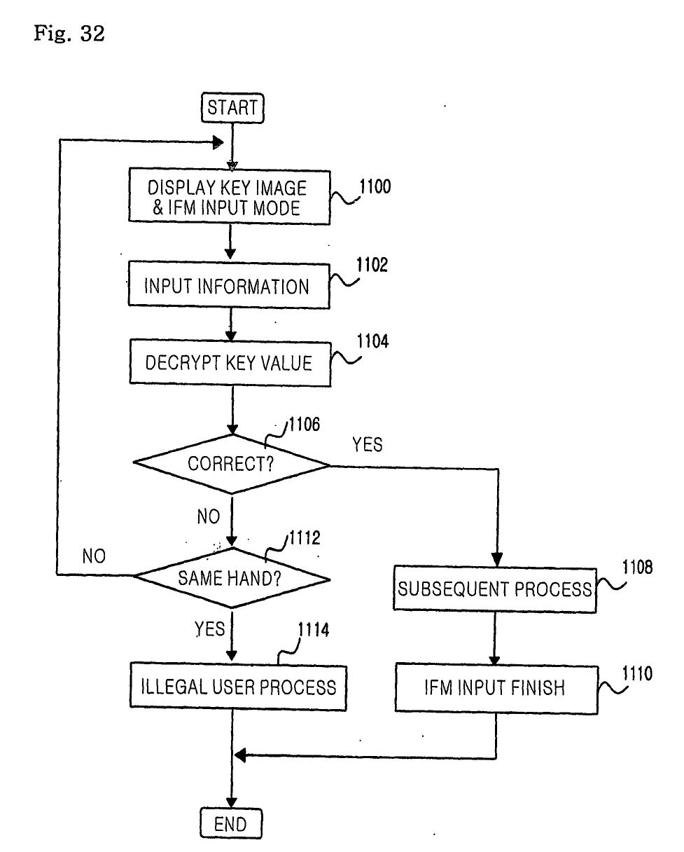

FIG. 32 is a flowchart illustrating a method of managing the same hand movement key input according to the present invention. In the present invention, in order to further improve security, if the same hand movement key is inputted instead of a correct key value when a key value such as a password is inputted, it is considered as an illegal use signal. A key image is first displayed and the process enters an information input mode where it waits for a user's inputting information (1100). In step 1102, if the user inputs information, the inputted information is decrypted as key values (1104). It is then determined whether the key values inputted by the user are correct (1106). If it is determined that the key values inputted by the user are correct, it is determined whether the user is a legal user, a subsequent process is performed (1108) and the input of information is finished (1110).

In the above, the legal user information that is compared with the decrypted key values in order to determine whether the key values are correct key values, is mostly built in case of a door lock. In case of ATM or APT, the legal user information is inputted from a bank's server corresponding to account information inputted through a card or a bankbook. If it is determined that the key values inputted by the user are incorrect in step 1106, it is determined whether the key values inputted in step 1112 are one of the same hand movement key values of the correct key values. If it is determined that the key value is not one of the same hand movement key values, the process waits for the re-entry of the user (1100). If it is determined that the key value is one of the same hand movement key values, it is processed as an illegal use since there is a possibility that the user may be an illegal user who peeped the user's key input hand movements (1114). In case of the illegal use process, the use of a corresponding card is temporarily stopped, a message notifying the user of the illegal use may be sent to the user, etc. In another embodiment, only when the number of times of the same hand movement keys accumulated exceeds a predetermined number of times, it is processed as the illegal use.

### INDUSTRIAL APPLICABILITY

According to the present invention, it is possible to prevent a peeper from decrypting a user's information by peeping the user's hand movements when the user inputs information. Furthermore, it is possible to prevent a peeper from decrypting a user's input information by collecting the input traces such as hand traces or fingerprints, abrasion of a keypad, etc. on a key input means. Incidentally, convenience and security in inputting keys can be improved at the same time and an illegal use attempt by a peeper can be prevented. It is also possible to prevent a peeper from decrypting information that is being inputted by a user, by peeping the information through a keyboard from the side.

While the present invention has been described with reference to the particular illustrative embodiments, it is not to be restricted by the embodiments, but only by the appended claims. It is to be appreciated that those skilled in the art can change or modify the embodiments, without departing from the scope and spirit of the present invention.

What is claimed is:

1. An information input apparatus whose key arrangement is variable, comprising:
a key display section for displaying elements of a key image of a matrix shape;
a key input section for receiving information of a corresponding key at a predetermined location of the key image displayed on the key display section; and
an input controller for generating an image of predetermined key arrangement selected among a plurality of key images in which numeric keys are shift-arranged so that there is no crossing in an neighboring numeral traffic line, providing the generated image to the key display section, and converting the information inputted through the key input section into an actual key value based on the predetermined key arrangement.

2. The information input apparatus as claimed in claim 1, further comprising an ambient light shielding filter attached to the front of the key display section.

3. The information input apparatus as claimed in claim 2, wherein the ambient light shielding filter is an orthogonal two-fold shielding filter.

4. The information input apparatus as claimed in claim 1, wherein the input controller further comprises a user input section, and displays the key image of the predetermined arrangement type on the key display section based on the signal inputted through the user input section.

5. The information input apparatus as claimed in claim 1, wherein the matrix elements are shifted in a direction moving from a left upper portion of the keypad to a right lower portion of the keypad.

6. The information input apparatus as claimed in claim 1, wherein the key arrangement includes non-numeric keys whose location is all fixed.

7. The information input apparatus as claimed in claim 1, wherein the key arrangement includes non-numeric keys that are shift-arranged along with the numeric keys.

8. The information input apparatus as claimed in claim 1, wherein the key arrangement comprises a plurality of non-numeric keys having one side fixed to a predetermined location and the other randomly arranged.

9. The information input apparatus as claimed in claim 1, wherein the key arrangement comprises non-numeric keys all of which are randomly arranged.

10. The information input apparatus as claimed in claim 1, wherein the key arrangement comprises numeric keys and non-numeric keys, the numeric keys experience a square rotary shift in the clockwise or counterclockwise direction, and the starting point of the numeric keys is arbitrarily selected.

11. The information input apparatus as claimed in claim 10, wherein the non-numeric keys are fixed at the center.

12. The information input apparatus as claimed in claim 1, wherein multiple character keys are allocated to the numeric keys.

13. A method for controlling an information input apparatus of variable key arrangement, wherein the information input apparatus includes a key display section for displaying a key image of a matrix shape and a key input section for receiving information of a corresponding key at a predetermined location of the key image displayed on the key display section, comprising the steps of:
displaying, an image of predetermined key arrangement selected among a plurality of key images in which numeric keys are shift-arranged so that there is no crossing in an neighboring numeral traffic line, on the key display section, and then waiting for a user's key input; and
decrypting the information inputted through the key input section as an actual key value based on the predetermined key arrangement.

14. The method as claimed in claim 13, further comprising the step of selecting an image of other key arrangement if the user chooses to change the key arrangement.

15. The method as claimed in claim 13, further comprising the step of selecting an image of other key arrangement every key input of a predetermined number of times.

16. A method for controlling an information input apparatus of variable key arrangement, wherein the information input apparatus includes a key display section for displaying a key image of a matrix shape and a key input section for receiving information of a corresponding key at a predetermined location of the key image displayed on the key display section, comprising the steps of:
displaying a key image of predetermined arrangement on the key display section and then waiting for key input;
if the key input is made, decrypting the information by the key input as an actual key value based on the predetermined key image arrangement;
comparing the decrypted key value with legal user information to determine whether the decrypted key value is a key value of the legal user or the same hand movement key value; and
if the decrypted key value is the key value of the legal user, performing a subsequent process, if the decrypted key value is the same hand movement key value, performing an illegal use process, and if the decrypted key value is neither the key value of the legal user nor the same hand movement key value, waiting for key input again.

17. The method as claimed in claim 16, wherein the legal user information is inputted corresponding to account information inputted by a card or a bankbook, and the illegal use process includes temporarily stopping the use of the card or bankbook.

18. The method as claimed in claim 16, wherein the illegal use process includes notifying the legal user or an administrator of the information input apparatus of the illegal use fact.

19. The method as claimed in claim 16, wherein the illegal use process is performed only when the same hand movement key input is performed in excess of a predetermined number of times.

20. A private information input system for preventing the drain of information through peeping, comprising:
means for generating a key image;
means for generating a masking image that masks the key image;
means for generating an image sequence for the key image and the masking image;
a key display section for displaying the key image and the masking image based the image sequence;
a key input section for receiving information of a corresponding key at a predetermined location of the key image displayed on the key display section; and
a private input section control means for converting the information inputted through the key input section into an actual key value according to the key image.

21. The private information input system as claimed in claim 20, wherein the means for generating the key image generates a key image whose key arrangement varies.

22. The private information input system as claimed in claim 20, further comprising a shutter opening/shutting means which has a shutter section and a shutter controller for opening/shutting the shutter section according to a shutter opening/shutting sequence corresponding to the image sequence.

23. The private information input system as claimed in claim 22, wherein the shutter opening/shutting means further comprises a sensor for sensing a user's use and informing the private input section control means of the fact.

24. The private information input system as claimed in claim 20, further comprising an ambient light shielding filter attached to the front of the key display section.

25. The private information input system as claimed in claim 20, further comprising a user authentication section for determining whether the user is a legal user.

26. The private information input system as claimed in claim 20, wherein the key image generating means decides a key arrangement type, and generates a key image of a current time point by randomly selecting one key arrangement having the decided key arrangement type.

27. The private information input system as claimed in claim 20, wherein the masking image causes a mixed image generated from the key image and the masking image to be seen to have a specific meaning regardless of the key image from naked eyes.

28. The private information input system as claimed in claim 27, wherein a key display unit of the key display section is composes of a LED.

29. The private information input system as claimed in claim 27, wherein a key display unit of the key display section is composed of 7-segment LED, and the masking image causes a mixed image generated from the key image and the masking image to be seen as “8” from naked eyes.

30. The private information input system as claimed in claim 20, wherein the masking image has a shape in which all the numerals except for numerals corresponding to the key image are overlapped.

31. The private information input system as claimed in claim 20, wherein the key image comprises two or more element images that display a predetermined numeral when being mixed.

32. The private information input system as claimed in claim 20, further comprising means for generating an intermediate state image between the key image and the masking image; wherein the image sequence generating means generates an image sequence for the intermediate state image, the key image and the masking image; and the key display section displays the intermediate state image, the key image and the masking image according to the image sequence.
